(19) United States
(12) Patent Application Publication
(10) Pub. No.: US 2023/0113328 A1
(43) Pub. Date: Apr. 13, 2023

(54) DEVICE AND METHOD FOR REMOVING ELECTRONIC COMPONENT AND METHOD FOR MANUFACTURING LED PANEL

(71) Applicant: ASTI GLOBAL INC., TAIWAN, Taichung City (TW)

(72) Inventors: JIA-WEI JHANG, Taichung City (TW); CHUN-LIANG CHIU, Taichung City (TW); SHENG-CHE HUANG, Taichung City (TW)

(21) Appl. No.: 17/864,385

(22) Filed: Jul. 13, 2022

(30) Foreign Application Priority Data
Oct. 12, 2021 (TW) 110137733

(51) Int. Cl. H01L 25/075; G09F 9/33

(52) U.S. Cl. CPC H01L 25/0753; G09F 9/33

(57) ABSTRACT

A device for removing electronic components includes a mounting platform, an energy beam generating appliance and a guiding mechanism. The mounting platform is adapted to mount a substrate in place. The energy beam generating appliance generates and emits an energy beam onto the mounting platform. The guiding mechanism guides the energy beam to a specific position on the mounting platform according to a signal. A method using the device to remove electronic components and a method including the aforesaid removal method to manufacture LED panels are further provided.

### CROSS-REFERENCE TO RELATED APPLICATION

This non-provisional application claims priority under 35 U.S.C. § 119(a) on Patent Application No(s). 110137733 filed in Taiwan, R.O.C. on Oct. 12, 2021, the entire contents of which are hereby incorporated by reference.

### BACKGROUND OF THE INVENTION

### 1. Field of the Invention

The present disclosure relates to a device and method for removing electronic components and a method for manufacturing light-emitting diode (LED) panels, and in particular to a device for removing a specific one of a plurality of electronic components quickly and selectively, a method using the device to remove electronic components, and a method including the aforesaid removal method to manufacture LED panels.

### 2. Description of the Related Art

A major category of existing commercially-available display devices is LED panel displays. In general, the manufacturing process of LED panel products entails performing epitaxy, mass transfer, die attachment and bonding. The mass transfer involves placing LEDs on a target panel or substrate by MEMS array technology and fixing the placed LEDs to the target panel or substrate by a means of attachment, such as solder. Thus, upon electrical conduction, the LEDs densely arranged on the panel get excited to emit light in different colors, respectively, thereby enabling high-saturation visual perception.

### BRIEF SUMMARY OF THE INVENTION

Mass transfer necessitates removal from the panel of defective LED chips or LED chips badly aligned in position or height. However, existing prior art is not effective in removing from a panel any chip otherwise attached to a specific position on the panel but requires moving a removal tool, such as a clamping jaw or laser welder, across the chips consecutively to above the chip to be removed before the removal operation begins. The removal process carried out with the removal tool is time-consuming. The removal tool is likely to hit and damage any other devices in the vicinity of the panel.

In view of the aforesaid drawbacks of the prior art, it is an objective of the disclosure to provide a device for removing a specific one of a plurality of electronic components quickly and selectively, so as to enhance removal efficiency and reduce the likelihood of mutual collisions of surrounding devices.

The disclosure provides a device for removing electronic components, including a mounting platform, an energy beam generating appliance and a guiding mechanism. The mounting platform is adapted to mount a substrate in place. The energy beam generating appliance generates and emits an energy beam onto the mounting platform. The guiding mechanism guides the energy beam to a specific position on the mounting platform according to a signal.

In an embodiment, the guiding mechanism includes a galvo mirror for reflecting the energy beam to the specific position.

In an embodiment, the energy beam is a laser beam.

In an embodiment, the device for removing electronic components further includes a cleaning device. The cleaning device is disposed on the mounting platform and corresponds in position to a cleaning area. The cleaning area is of a width greater than or equal to a width of the substrate in a scan direction.

In an embodiment, the cleaning device is an injection nozzle.

In an embodiment, the signal includes a coordinate information about the specific position.

The disclosure further provides a method for removing electronic components, including: providing a substrate, with a plurality of electronic components being mounted on the substrate and including at least one component to be removed; generating a signal including a coordinate information about the at least one component to be removed; providing an energy beam; guiding the energy beam to coordinates of the at least one component to be removed according to the signal and reducing the bonding force between the at least one component to be removed and the substrate with the energy beam; and removing the at least one component to be removed.

In an embodiment, the method involves using an air current to remove the component to be removed.

In an embodiment, the electronic components are LED chips.

The disclosure further provides a method for manufacturing LED panels, including using the method for removing electronic components to remove LEDs.

Therefore, the disclosure provides a device and method for removing electronic components, using a guiding mechanism to guide an energy beam to a specific position on a mounting platform according to a signal, using the energy beam to reduce a bonding force between a component to be removed and a substrate, so as to remove the component to be removed. According to the disclosure, the method for manufacturing LED panels includes the method for removing electronic components to thereby remove a specific one of a plurality of electronic components quickly and selectively, so as to enhance removal efficiency and reduce the likelihood of mutual collisions of surrounding devices.

The aforesaid features and advantages of the disclosure are hereunder illustrated with embodiments, depicted with accompanying drawings, and described below.

### BRIEF DESCRIPTION OF THE DRAWINGS

FIG. 1 is a front view of a device for removing electronic components according to an embodiment of the disclosure.

FIG. 2 is a top view based on FIG. 1.

FIG. 3 is a schematic view of the process flow of a method for removing electronic components according to an embodiment of the disclosure.

FIG. 4 is a front view of how an energy beam is emitted from an energy beam generating appliance in FIG. 1 according to a signal and guided with a guiding mechanism to a specific position on a substrate according to the disclosure.

FIG. 5 is a top view based on FIG. 4.

FIG. 6 is a top view of a cleaning device removing a component to be removed.

FIG. 7 is a top view of a recycling device recycling a component to be removed.

FIG. 8 is a top view of a mounting platform movable relative to the energy beam generating appliance and the guiding mechanism.

### DETAILED DESCRIPTION OF THE INVENTION

The above and other features and advantages of the disclosure are depicted by accompanying drawings, illustrated by embodiments and described below. Direction-related terms, such as “on,” “under,” “left,” “right,” “front” and “rear,” used in the description of the embodiments below are applicable to the accompanying drawings only. Thus, the direction-related terms are descriptive rather than restrictive of the disclosure. Identical or similar reference numerals used in the embodiments below denote identical or similar components.

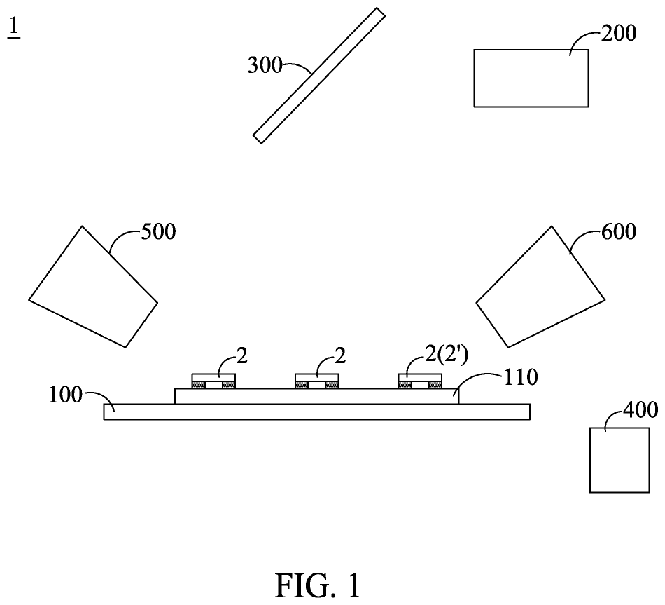

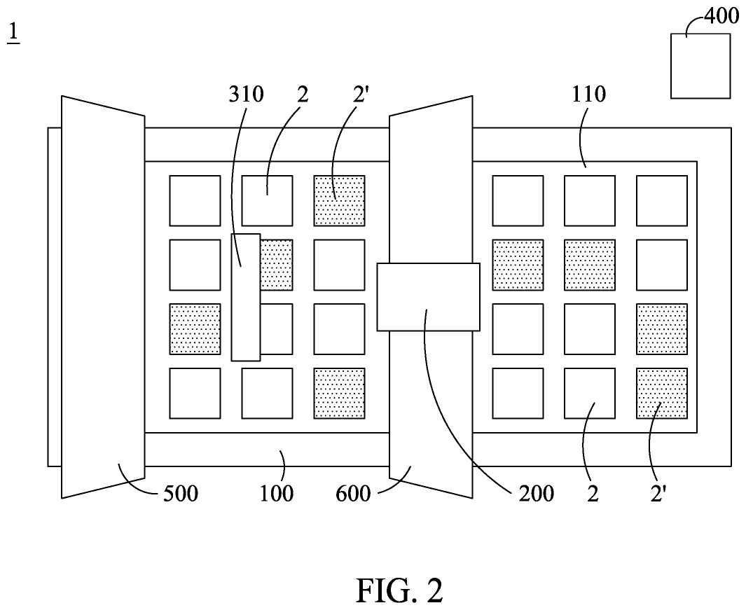

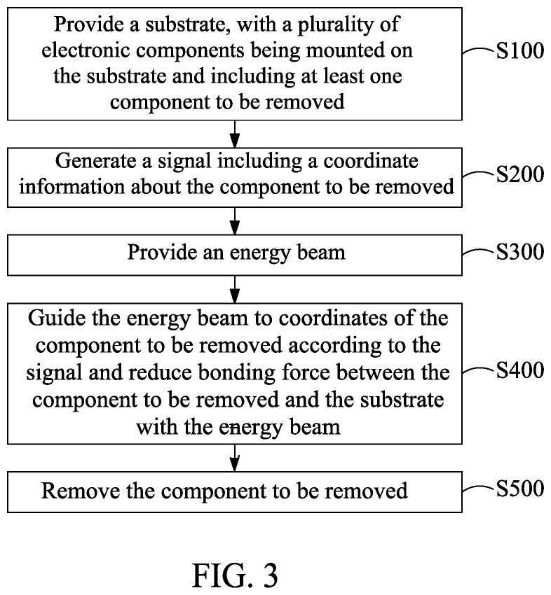

Refer to FIG. 1 through FIG. 3. FIG. 1 is a front view of a device for removing electronic components according to an embodiment of the disclosure. FIG. 2 is a top view based on FIG. 1. FIG. 3 is a schematic view of the process flow of a method for removing electronic components according to an embodiment of the disclosure. In this embodiment, a device 1 for removing electronic components removes, with a method for removing electronic components, a specific one of a plurality of electronic components 2. Specifically, the device 1 for removing electronic components includes a mounting platform 100, an energy beam generating appliance 200 and a guiding mechanism 300. The mounting platform 100 is adapted to mount a substrate 110 in place. The energy beam generating appliance 200 and the guiding mechanism 300 are mounted on the mounting platform 100. In this embodiment, a method for removing electronic components includes the steps of: providing a substrate 110, wherein a plurality of electronic components 2 are mounted on the substrate 110 and include at least one component 2′ to be removed (step S100); generating a signal including a coordinate information about the component 2′ to be removed (step S200); providing an energy beam E (step S300); guiding the energy beam E to the coordinates of the component 2′ to be removed according to the signal and reducing the bonding force between the component 2′ to be removed and the substrate 110 with the energy beam E (step S400); and removing the component 2′ to be removed (step S500).

For example, the mounting platform 100 is a movable track or a rigid plate and is adapted to mount the substrate 110 with the electronic components 2. In this embodiment, the electronic components 2 are, for example, LED chips or any other electronic components capable of emitting light; however, the disclosure is not limited thereto. The electronic components 2 include the component 2′ to be removed from the substrate 110. The component 2′ to be removed is, for example, a diode chip not capable of emitting light or a defective chip badly aligned in position or height during the transfer step; and the removal is achieved by a physical or energy means.

For example, the energy beam generating appliance 200 is a laser generator for generating and emitting a laser beam to the mounting platform 100. However, in another possible embodiment, the energy beam generating appliance 200 may also be a device which generates high-heat, low-frequency visible light. The guiding mechanism 300 guides the energy beam generated by the energy beam generating appliance 200 to a specific position on the mounting platform 100 according to the signal received. For example, the guiding mechanism 300 includes a galvo mirror 310. The galvo mirror 310 reflects the energy beam to a specific position. The position and orientation of the galvo mirror 310 relative to the energy beam generating appliance 200 are adjustable; thus, a user can adjust the position and orientation of the galvo mirror 310 relative to the energy beam generating appliance 200 to allow the energy beam to be reflected to a position anticipated by the user. Optionally, the guiding mechanism 300 further includes a lens for converging or diverging the energy beam, a chamber for adjusting energy beam power, and a slit for filtering or gathering any other energy beam sources; however, the disclosure is not limited thereto.

Preferably, the device 1 for removing electronic components further includes a signal unit 400, a cleaning device 500 and a recycling device 600. The signal unit 400 is electrically connected to the energy beam generating appliance 200 and the guiding mechanism 300 to provide information required for the energy beam generating appliance 200 to generate the energy beam E and for the guiding mechanism 300 to guide the energy beam E. The cleaning device 500 and the recycling device 600 are mounted on the mounting platform 100 (on the substrate 110 in this embodiment) to clean and recycle the component 2′ to be removed, respectively.

For example, the signal unit 400 is a signal generator or a controller for generating a programmed signal to be sent to the energy beam generating appliance 200 and the guiding mechanism 300 wiredly or wirelessly. The signal sent to the energy beam generating appliance 200 is indicative of, for example, the point in time at which the energy beam is emitted, the power of the energy beam, and the time interval required to keep emitting the energy beam. The signal sent to the guiding mechanism 300 includes, for example, a coordinate information required for guiding the energy beam to a specific position. After the guiding mechanism 300 has received the coordinate information, the position and orientation of the galvo mirror 310 relative to the energy beam generating appliance 200 can be adjusted, allowing the energy beam to precisely fall onto a target position. When the coordinate information is in a plural number, the guiding mechanism 300 can receive the coordinate information and then enable the energy beam to fall onto the target positions consecutively and precisely.

The cleaning device 500 is, for example, an injection nozzle. Upon reduction of the bonding force between the component 2′ to be removed and the substrate 110 with the energy beam E, the cleaning device 500 blows a pressurized air current whereby the component 2′ to be removed from the substrate 110 is moved away from its original position thereon, and thus the surface of the substrate 110 stays clean. However, in another possible embodiment, the cleaning device 500 is a mechanical arm adapted to allow soft bristles to be protruded, and the soft bristles clean the component 2′ to be removed once and for all after the energy beam E reduces the bonding force. However, the disclosure is not limited thereto.

The recycling device 600 is, for example, a suction nozzle for taking in, by suction under a negative pressure, the component 2′ cleaned with the cleaning device 500; thus, if the light-emitting capability of the component 2′ to be removed functions well, the component 2′ recycled by the recycling device 600 can undergo the transfer step once again, thereby precluding a waste of the electronic components 2. Furthermore, the recycling device 600 preferably corresponds in position to the cleaning device 500, and is more preferably disposed on two opposing sides of the mounting platform 100, so as to speed up the removal step of the electronic components 2.

In this embodiment, the signal unit 400 is also electrically connected to both the cleaning device 500 and the recycling device 600. After the energy beam generating appliance 200 and the guiding mechanism 300 have enabled the separation of the component 2′ to be removed and the substrate 110 according to the signal emitted from the signal unit 400, the signal unit 400 sends the signal to the cleaning device 500 and recycling device 600 at any time, such that the cleaning device 500 and recycling device 600 consecutively clean and recycle the component 2′ to be removed, respectively.

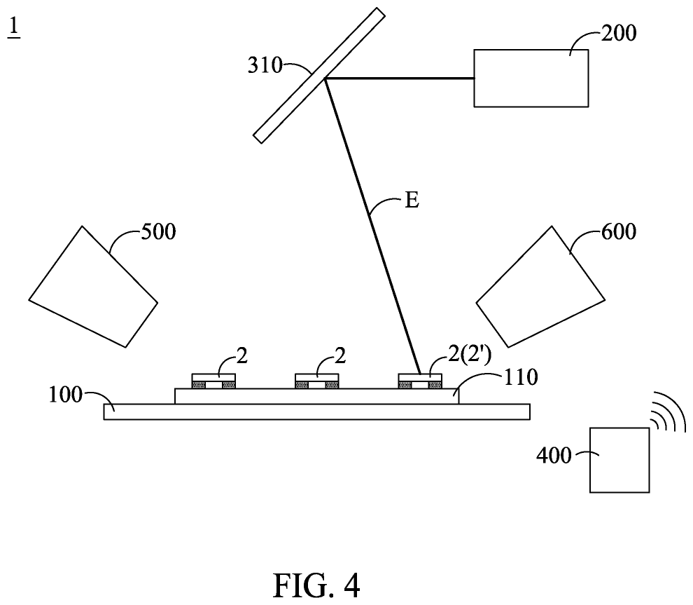

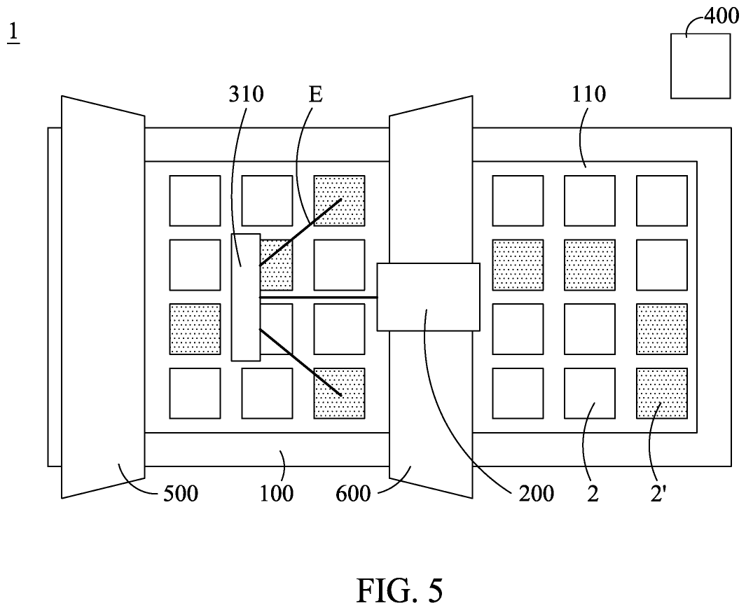

Refer to FIG. 4 and FIG. 5. FIG. 4 is a front view of how an energy beam is emitted from the energy beam generating appliance according to a signal and guided with the guiding mechanism to a specific position on the substrate. FIG. 5 is a top view based on FIG. 4. As shown in the diagrams, when the signal unit 400 generates and sends a signal to the energy beam generating appliance 200 and the guiding mechanism 300, the energy beam generating appliance 200 generates and emits at a specific point in time the energy beam E with specific power and time interval according to the signal. The guiding mechanism 300 adjusts the position or orientation of the galvo mirror 310 and any other possible optical components according to the signal from the signal unit 400 to guide the energy beam E to the coordinates of the component 2′ (dotted in FIG. 5) on the substrate 110, thereby reducing the bonding force between the component 2′ to be removed and the substrate 110 with the energy beam E. The component 2′ to be removed is, for example, soldered to the substrate 110 with solder. The guiding mechanism 300 guides the energy beam E to the solder to melt it, allowing the component 2′ to be removed to separate from the substrate 110.

In this embodiment, one single energy beam E is, for example, emitted at the same time, and the galvo mirror 310 consecutively varies its own position and orientation to reflect the energy beam E to the component 2′ to be removed. However, the disclosure is not limited thereto. In another possible embodiment, the energy beam generating appliance 200 emits a plurality of energy beams E once and for all, whereas the guiding mechanism 300 includes a plurality of galvo mirrors 310 and optical components corresponding in position thereto, respectively, and guides once and for all the plurality of energy beams E to all the components 2′ within a processing area, so as to further speed up the automated process of removing the components 2′ to be removed.

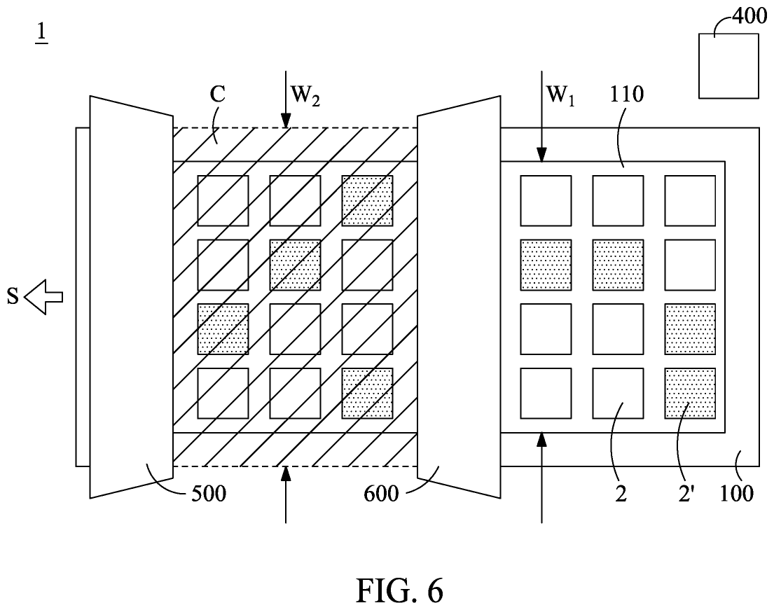

Referring to FIG. 6, there is shown a top view of a cleaning device removing a component to be removed. As shown in the diagram, the cleaning device 500 corresponds in position to a cleaning area C, and a width W₂ of the cleaning area C is greater than or equal to a width W₁ of the substrate 110 in a scan direction S. Upon separation of the component 2′ to be removed and the substrate 110, the cleaning device 500 blows an air current according to the signal sent from the signal unit 400, so as to blow the component 2′ to be removed away from the substrate 110. Moreover, since the width W₂ of the cleaning area C (which the cleaning device 500 corresponds in position to) is greater than or equal to the width W₁ of the substrate 110 in the scan direction S (for example, the width of the injection nozzle is greater than the width of the substrate 110), the cleaning device 500 can, once and for all, remove all the components 2′ to be removed within the cleaning area C (upon reduction of the bonding force between each component 2′ to be removed and the substrate 110 with the energy beam E), thereby enhancing the efficiency of removal of specific electronic components 2. The cleaning device 500 can move forward or backward in the scan direction S to remove from the substrate 110 all the component 2′ separated from the substrate 110.

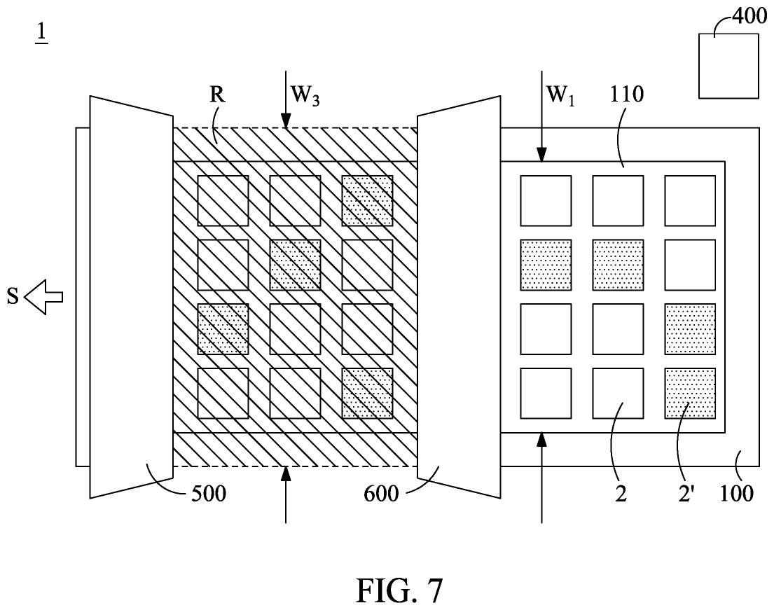

Referring to FIG. 7, there is shown a top view of the recycling device recycling a component to be removed. Likewise, the recycling device 600 corresponds in position to a recycling area R, and a width W₃ of the recycling area R in the scan direction S is greater than or equal to the width W₁ of the substrate 110. After the cleaning device 500 has moved the components 2′ to be removed away from their original positions, the recycling device 600 generates a negative pressure according to the signal sent from the signal unit 400 to recycle the displaced components 2′ to be removed. Since the width W₃ of the recycling area R is greater than or equal to the width W₁ of the substrate 110 in the scan direction S, the recycling device 600 recycles the displaced components 2′ to be removed collectively once and for all rather than one by one. Regarding the process flow in this embodiment, the cleaning step precedes the recycling step; however, the disclosure is not limited thereto. In a variant embodiment, the cleaning device 500 and recycling device 600 operate simultaneously, such that the components 2′ to be removed are (upon the reduction of the bonding force between the components 2′ to be removed and the substrate 110 with the energy beam E) subjected to the air current generated by the cleaning device 500 and the negative pressure generated by the recycling device 600 simultaneously, thereby speeding up the removal step.

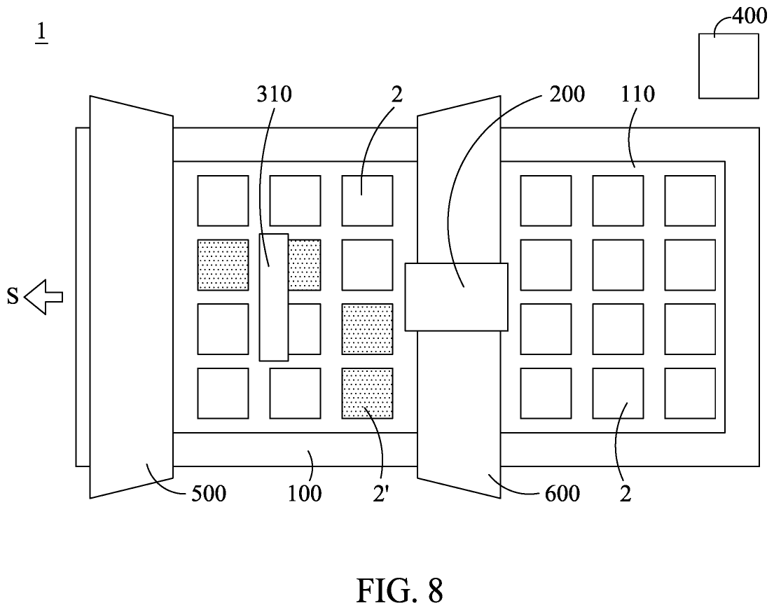

Referring to FIG. 8, there is shown a top view of a mounting platform movable relative to the energy beam generating appliance and the guiding mechanism. Upon removal of the components 2′ to be removed within the cleaning area C and the recycling area R from the substrate 110, the mounting platform 100 moves in the scan direction S relative to the energy beam generating appliance 200, guiding mechanism 300, cleaning device 500 and recycling device 600 to allow the next batch of the component 2′ to be removed to lie within the cleaning area C and recycling area R, thereby facilitating the overall operation. In this embodiment, the mounting platform 100 moves relative to the energy beam generating appliance 200, guiding mechanism 300, cleaning device 500 and recycling device 600 in the scan direction S; however, in another possible embodiment, the energy beam generating appliance 200, guiding mechanism 300, cleaning device 500 and recycling device 600 move relative to the mounting platform 100 in a direction opposite to the scan direction S to achieve the same effect.

The disclosure further provides a method for manufacturing LED panels, and the method includes the aforesaid method for removing electronic components from the substrate 110.

The disclosure is disclosed above by preferred embodiments. However, the embodiments are illustrative of the disclosure only, but shall not be interpreted as restrictive of the scope of the disclosure. Hence, all equivalent changes and modifications made by persons skilled in the art to the embodiments shall be deemed falling within the scope of the disclosure.

What is claimed is:

1. A device for removing electronic components, comprising:
a mounting platform adapted to mount a substrate in place;
an energy beam generating appliance for generating and emitting an energy beam to the mounting platform; and
a guiding mechanism for guiding the energy beam onto a specific position on the mounting platform according to a signal.

2. The device of claim 1, wherein the guiding mechanism comprises a galvo mirror for reflecting the energy beam to the specific position.

3. The device of claim 1, wherein the energy beam is a laser beam.

4. The device of claim 1, further comprising a cleaning device disposed on the mounting platform and corresponding in position to a cleaning area, with the cleaning area being of a width greater than or equal to a width of the substrate in a scan direction.

5. The device of claim 4, wherein the cleaning device is an injection nozzle.

6. The device of claim 1, wherein the signal comprises a coordinate information about the specific position.

7. A method for removing electronic components, comprising:
providing a substrate, with a plurality of electronic components being mounted on the substrate and including at least one component to be removed;
generating a signal including a coordinate information about the at least one component to be removed;
providing an energy beam;
guiding the energy beam to coordinates of the at least one component to be removed according to the signal and reducing bonding force between the at least one component to be removed and the substrate with the energy beam; and
removing the at least one component to be removed.

8. The method of claim 7, wherein the energy beam is a laser beam.

9. The method of claim 7, wherein the at least one component to be removed is removed with an air current.

10. The method of claim 7, wherein the plurality of electronic components are LED chips.

11. A method for manufacturing LED panels, adapted to remove LEDs with the method of claim 7.

12. A method for manufacturing LED panels, adapted to remove LEDs with the method of claim 8.

13. A method for manufacturing LED panels, adapted to remove LEDs with the method of claim 9.

14. A method for manufacturing LED panels, adapted to remove LEDs with the method of claim 10.
